(19) United States
(12) Patent Application Publication
(10) Pub. No.: US 2014/0349235 A1
(43) Pub. Date: Nov. 27, 2014

(54) DRAWING APPARATUS, AND METHOD OF MANUFACTURING ARTICLE

(71) Applicant: CANON KABUSHIKI KAISHA, Tokyo (JP)

(72) Inventor: Keisuke NAKAMURA, Utsunomiya-shi (JP)

(73) Assignee: CANON KABUSHIKI KAISHA, Tokyo (JP)

(21) Appl. No.: 14/284,707

(22) Filed: May 22, 2014

(30) Foreign Application Priority Data
May 24, 2013 (JP) 2013-110392

(51) Int. Cl. H01J 37/317; H01J 37/30

(52) U.S. Cl. CPC H01J 37/3174; H01J 37/3002
USPC 430/296; 250/492.2; 430/325

(57) ABSTRACT

The present invention provides a drawing apparatus for performing drawing on a substrate with a plurality of charged particle beams, the apparatus including an aperture array member in which a plurality of first apertures, for generating the plurality of charged particle beams, is formed, and a generating device configured to individually generate electric potentials in a plurality of regions of the aperture array member, wherein each of the plurality of regions corresponds to at least one of the plurality of first apertures.

### BACKGROUND OF THE INVENTION

1. Field of the Invention

The present invention relates to a drawing apparatus, and a method of manufacturing an article.

2. Description of the Related Art

As a drawing apparatus for performing drawing on a substrate with charged particle beams, Japanese Patent Laid-Open No. 9-7538 proposes a drawing apparatus including a charged particle optical system for each charged particle beam. In such a drawing apparatus, since the charged particle optical systems individually exist, a crossover where all the plurality of charged particle beams focus is not formed. Hence, the drawing apparatus is advantageous in increasing the number of charged particle beams and thus increasing the irradiation current upon drawing (that is, improving the throughput) because the influence of the space-charge effect (Coulomb effect) is small.

On the other hand, increasing the irradiation current to obtain high throughput also causes an increase in the amount of a current entering an aperture array member configured to generate the plurality of charged particle beams. Most of electron energy entering the aperture array member generally changes to heat. The heat can be problematic when the irradiation current is increased to obtain high throughput. Japanese Patent Laid-Open No. 2006-140267 proposes a technique of constructing a plurality of stages of aperture array members to reduce the heat generated in each aperture array member.

However, unevenness of irradiation of charged particle beams or a decrease in numerical aperture caused by hydrocarbon adhesion in the apertures of an aperture array member results in an uneven heat amount (heat density) in the aperture array member that determines the final shape of a charged particle beam. This also applies to a case where a plurality of stages of aperture array members are constructed. Such an uneven heat amount causes uneven deformation (including uneven changes of aperture positions) of the aperture array member by uneven thermal expansion.

### SUMMARY OF THE INVENTION

The present invention provides, for example, a drawing apparatus advantageous in terms of reducing uneven deformation of an aperture array member caused by a charged particle beam incident thereon.

According to one aspect of the present invention, there is provided a drawing apparatus for performing drawing on a substrate with a plurality of charged particle beams, the apparatus including an aperture array member in which a plurality of first apertures, for generating the plurality of charged particle beams, is formed, and a generating device configured to individually generate electric potentials in a plurality of regions of the aperture array member, wherein each of the plurality of regions corresponds to at least one of the plurality of first apertures.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus according to the first embodiment of the present invention.

FIGS. 2A to 2D are views for explaining the arrangement of a second aperture array of the drawing apparatus shown in FIG. 1.

FIG. 3 is a schematic view showing the arrangement of a drawing apparatus according to the second embodiment of the present invention.

FIGS. 4A to 4C are views for explaining a first shield electrode and a second shield electrode of the drawing apparatus shown in FIG. 3.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

### First Embodiment

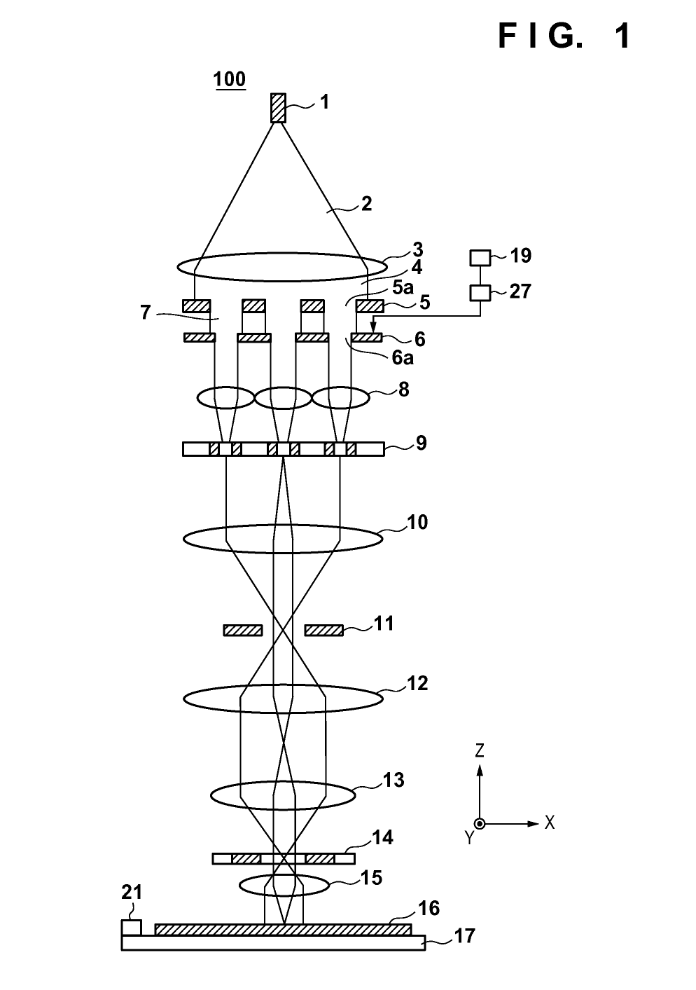

FIG. 1 is a schematic view showing the arrangement of a drawing apparatus 100 according to the first embodiment of the present invention. The drawing apparatus 100 is a lithography apparatus that performs drawing on a substrate with a plurality of charged particle beams (that is, draws a pattern on a substrate). The charged particle beam is not limited to an electron beam and can be, for example, an ion beam or the like.

The drawing apparatus 100 includes a charged particle source 1, a collimator lens 3, a first aperture array 5, a second aperture array 6, a focusing lens array 8, a blanker array 9, and a charged particle lens 10. The drawing apparatus 100 also includes a stop aperture array 11, charged particle lenses 12 and 13, a deflector 14, a charged particle lens 15, a substrate stage 17, a control unit 19, and a measurement unit 21.

The charged particle source 1 is a thermionic charged particle source including, for example, LaB₆ or BaO/W (dispenser cathode) in a charged particle beam emitting portion. A charged particle beam 2 emitted by the charged particle source 1 changes to a parallel charged particle beam 4 via the collimator lens 3 and enters the first aperture array 5.

Each of the first aperture array 5 and the second aperture array 6 is an aperture array member having apertures configured to divide the charged particle beam 4 into a plurality of charged particle beams 7 (that is, generate the plurality of charged particle beams 7). In this embodiment, the first aperture array 5 has a plurality of apertures 5a corresponding to a plurality of apertures 6a of the second aperture array 6. Each of the plurality of apertures 5a of the first aperture array 5 has dimensions larger than those of a corresponding one of the apertures 6a of the second aperture array 6. Hence, the plurality of charged particle beams 7 that have passed through the apertures 5a of the first aperture array 5 enter the second aperture array 6, and the apertures 6a of the second aperture array 6 form the shapes of the charged particle beams.

Each of the plurality of charged particle beams that have passed through the apertures 6a of the second aperture array 6 is focused by the focusing lens array 8 and forms an image on the blanker array 9. The blanker array 9 is a device including deflection electrodes (more specifically, deflection electrode pairs) that can individually be controlled. Under the control of the control unit 19, the blanker array 9 individually deflects the plurality of charged particle beams from the second aperture array 6, thereby performing blanking. For example, not to blank the charged particle beams, no voltage is applied to the deflection electrodes of the blanker array 9. To blank the charged particle beams, a voltage is applied to the deflection electrodes of the blanker array 9.

The charged particle beams deflected by the blanker array 9 are blocked by the stop aperture array 11 arranged at the subsequent stage of the blanker array 9 and set in a blanked state. On the other hand, the charged particle beams that are not deflected by the blanker array 9 are focused by the charged particle lenses 10, 12, 13, and 15 and form images on a substrate 16.

The deflector 14 is formed from electrodes (counter electrodes) facing each other, and deflects (scans) the charged particle beams focused on the substrate 16 by the charged particle lens 15. In this embodiment, to perform deflection of two stages for each of the X and Y directions, the deflector 14 is formed from four stages of counter electrodes.

The substrate stage 17 holds the substrate 16 and moves. The measurement unit 21 such as a Faraday cup that measures the charge amount of the charged particle beams from the charged particle lens 15 is arranged on the substrate stage 17.

The control unit 19 includes a CPU and a memory, and controls the whole (operation) of the drawing apparatus 100. The control unit 19 controls, for example, processing of drawing a pattern on the substrate 16.

To draw a pattern, the substrate stage 17 holding the substrate 16 is continuously moved in the x-axis direction, and charged particle beams on the substrate 16 are deflected in the y-axis direction by the deflector 14 based on the real-time measurement result (the position of the substrate stage 17) of a laser measuring device. At this time, the blanker array 9 blanks the charged particle beams in accordance with the drawing pattern. With this operation, a pattern can quickly be drawn on the substrate 16.

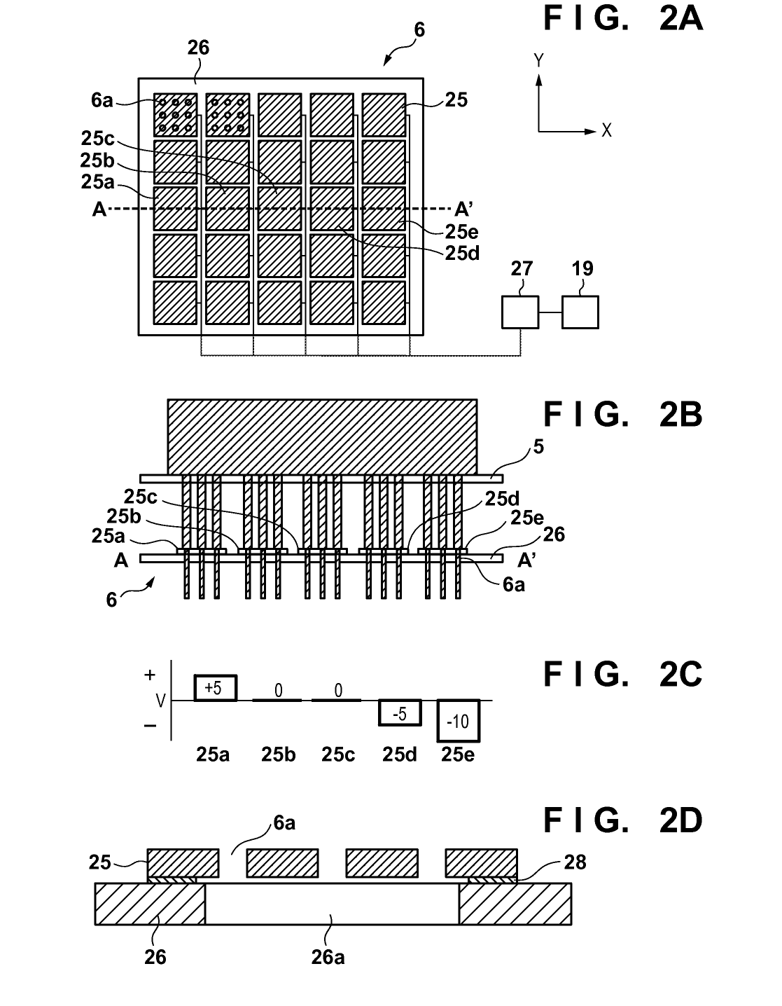

The arrangement of the second aperture array 6 according to this embodiment will be described in detail with reference to FIGS. 2A to 2D. In the second aperture array 6, for example, as shown in FIG. 2A, a plurality of regions 25 are set on the incident surface where charged particle beams enter. Each of the regions 25 corresponds to at least one of the plurality of apertures (first apertures) 6a. In this embodiment, 5 (rows)×5 (columns) regions 25 each corresponding to nine apertures 6a are set on a base 26. More specifically, as shown in FIG. 2D, the regions 25 are combined with the base 26 having apertures 26a via an insulating layer 28. As described above, in this embodiment, the regions 25 are arranged on the incident surface (charged particle source side) of the second aperture array 6. However, they may be arranged on the lower surface (substrate side) opposite to the incident surface of the second aperture array 6. An electric potential generation unit 27 configured to individually generate electric potentials for the respective regions 25 of the second aperture array 6 (that is, apply voltages to the respective regions 25) is combined with the regions 25 of the second aperture array 6. The regions 25 (electrodes) of the second aperture array 6 and the electric potential generation unit 27 function as a generation unit configured to individually generate electric potentials for the respective regions 25 of the second aperture array 6.

FIG. 2B is a sectional view of the second aperture array 6 in FIG. 2A taken along a line A-A′. FIG. 2C is a view showing examples of voltage values applied to regions 25a, 25b, 25c, 25d, and 25e shown in FIG. 2A. For example, in FIG. 2B, assume that the positions of the apertures 6a in the region 25a are displaced in the +X direction from the design positions (specifications), and the positions of the apertures 6a in the region 25e are displaced in the +X direction from the design positions. In this case, when the voltage values in the regions 25a, 25b, 25c, 25d, and 25e are changed, as shown FIG. 2C, the displacements of the apertures 6a in the region 25a and those of the apertures 6a in the region 25e can be reduced. More specifically, the electric potential generation unit 27 generates a positive electric potential for the region 25a. This makes it possible to correct (displace) the positions of the apertures 6a in the region 25a in the −X direction and reduce the displacements of the apertures 6a in the region 25a. Similarly, the electric potential generation unit 27 generates a negative electric potential for the region 25e. This makes it possible to correct (displace) the positions of the apertures 6a in the region 25e in the −X direction and reduce the displacements of the apertures 6a in the region 25e. When a finely set electric potential is generated for a region, for example, the region 25d between the region 25a and the region 25e, the displacements of the apertures 6a in the region 25e can be reduced more accurately.

The electric potentials to be generated by the electric potential generation unit 27 for the regions 25 set on the second aperture array 6 are controlled by the control unit 19. For example, the control unit 19 controls the electric potentials to be generated for the regions 25 set on the second aperture array 6 based on the positions of the apertures 6a (that is, at least one of the plurality of apertures) of the second aperture array 6. At this time, for example, the control unit 19 controls the electric potentials to be generated for the regions 25 set on the second aperture array 6 based on the positions of charged particle beams through the apertures 6a of the second aperture array 6 (that is, displacements from the design positions). The positions of the charged particle beams through the apertures 6a of the second aperture array 6 can be measured using the measurement unit 21 arranged on the substrate stage 17. More specifically, the position of a charged particle beam entering the substrate 16 is obtained from the measurement result of the measurement unit 21. A position at which a charged particle beam has passed through the aperture 6a of the second aperture array 6 is specified based on the position of the charged particle beam. The position at which the charged particle beam has passed through the aperture 6a of the second aperture array 6 is converted into a displacement from the design position of the aperture 6a of the second aperture array 6. The displacement from the design position of the aperture 6a of the second aperture array 6 can also be obtained from the temperature distribution and deformation amount distribution on the first aperture array 5 or second aperture array 6. In this case, the electric potentials to be generated for the regions 25 set on the second aperture array 6 are controlled based on a change amount from the initial state of the first aperture array 5 or second aperture array 6.

In this way, the drawing apparatus 100 decelerates or accelerates the charged particle beams passing through the apertures 6a of the second aperture array 6 by causing the electric potential generation unit 27 to individually generate electric potentials for the respective regions 25 set on the second aperture array 6. This makes it possible to adjust the kinetic energy of charged particle beams for each of the regions 25 set on the second aperture array 6 and reduce the displacements of the apertures 6a of the second aperture array 6 while maintaining the drawing performance of the drawing apparatus 100.

However, the regions 25 set on the second aperture array 6 change depending on the number or distribution of the apertures 6a of the second aperture array 6. For example, when the number of apertures 6a arranged in the X direction of the second aperture array 6 is different from the number of apertures 6a arranged in the Y direction, more regions 25 may be set in the direction in which more apertures 6a are arranged.

In this embodiment, a plurality of charged particle beams are generated by the two stages of aperture arrays, that is, the first aperture array 5 and the second aperture array 6. However, the number of stages of aperture arrays is not limited. One stage of aperture array or three or more stages of aperture arrays may be used.

### Second Embodiment

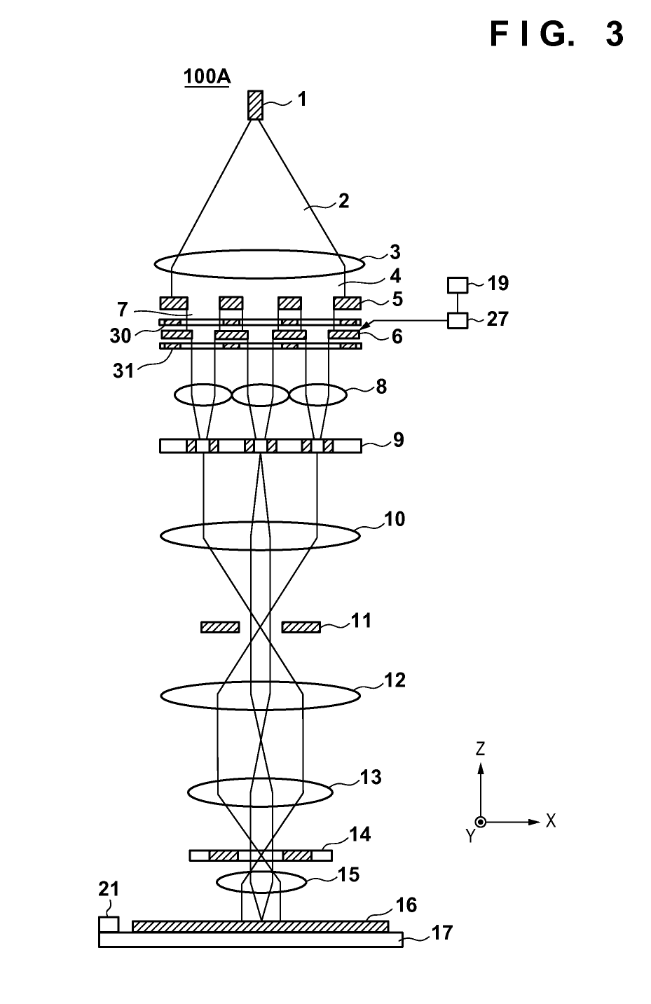

FIG. 3 is a schematic view showing the arrangement of a drawing apparatus 100A according to the second embodiment of the present invention. The drawing apparatus 100A is a lithography apparatus that performs drawing on a substrate with a plurality of charged particle beams (that is, draws a pattern on a substrate). The drawing apparatus 100A includes a first shield electrode 30 and a second shield electrode 31 in addition to the components of the drawing apparatus 100 shown in FIG. 1.

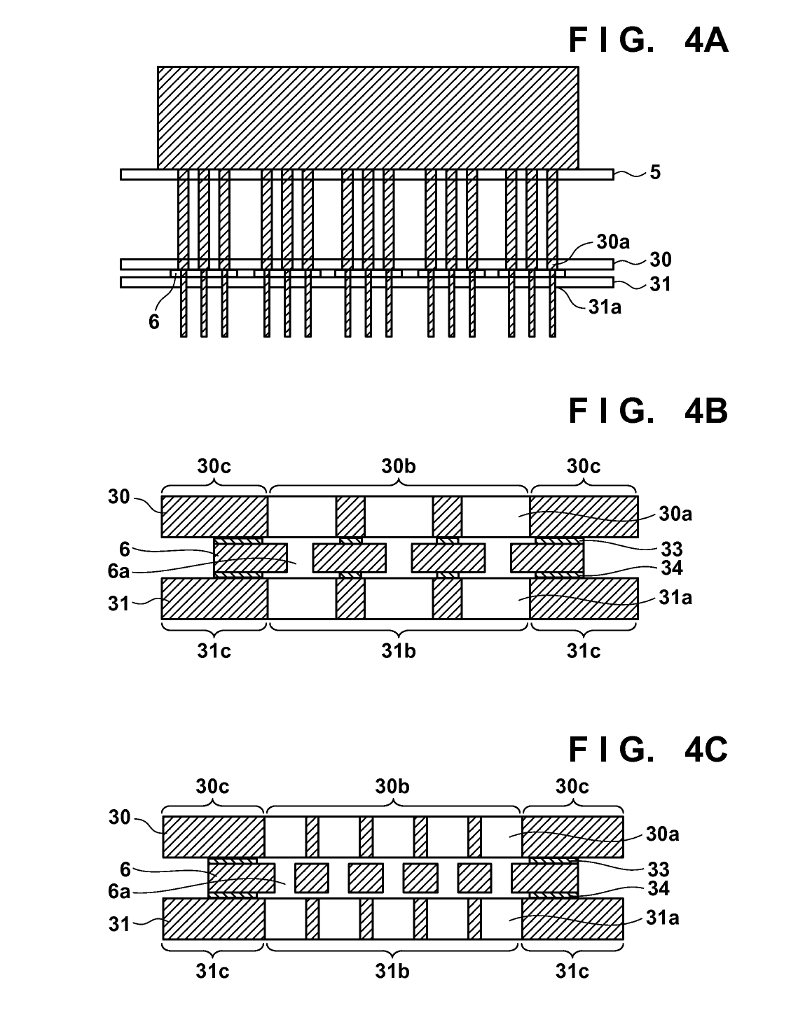

The first shield electrode 30 and the second shield electrode 31 will be described with reference to FIGS. 4A to 4C.

As shown in FIG. 4A, the first shield electrode 30 is arranged on the side of a charged particle source 1 with respect to a second aperture array 6 (a side opposite to a substrate), more specifically, between a first aperture array 5 and the second aperture array 6. The first shield electrode 30 has a plurality of apertures (second apertures) 30a corresponding to a plurality of apertures 5a of the first aperture array 5 and a plurality of apertures 6a of the second aperture array 6, respectively. Each of the plurality of apertures 30a of the first shield electrode 30 has dimensions larger than those of a corresponding one of the apertures 6a of the second aperture array 6. Charged particle beams that have passed through the apertures 30a of the first shield electrode 30 enter the second aperture array 6, and the apertures 6a of the second aperture array 6 form the shapes of the charged particle beams.

As shown in FIG. 4A, the second shield electrode 31 is arranged on the side of a substrate 16 with respect to the second aperture array 6, more specifically, between the second aperture array 6 and a focusing lens array 8. The second shield electrode 31 has a plurality of apertures (third apertures) 31a corresponding to the plurality of apertures 5a of the first aperture array 5 and the plurality of apertures 6a of the second aperture array 6, respectively. Each of the plurality of apertures 31a of the second shield electrode 31 has dimensions larger than those of a corresponding one of the apertures 6a of the second aperture array 6.

Since electric potentials are individually generated for regions 25 set on the second aperture array 6, an electric field may be generated in a direction perpendicular to the optical axis in accordance with the magnitude of the voltage in each region 25. In this case, charged particle beams may be bent by the electric field.

In this embodiment, the first shield electrode 30 and the second shield electrode 31 are respectively arranged on the upper side (the side of the charged particle source 1) and the lower side (the side of the substrate 16) of the second aperture array 6, thereby reducing (preventing) bending of charged particle beams. Hence, the first shield electrode 30 and the second shield electrode 31 are preferably grounded, though the present invention is not limited to this.

FIG. 4B is a view showing an example of the detailed arrangement of the second aperture array 6, the first shield electrode 30, and the second shield electrode 31. As shown in FIG. 4B, the first shield electrode 30 is combined with the second aperture array 6 via a first insulating layer 33, and the second shield electrode 31 is combined with the second aperture array 6 via a second insulating layer 34. The first insulating layer 33 is arranged in a peripheral region 30c that surrounds an aperture region 30b including a region where the plurality of apertures 30a of the first shield electrode 30 are formed. The second insulating layer 34 is arranged in a peripheral region 31c that surrounds an aperture region 31b including a region where the plurality of apertures 31a of the second shield electrode 31 are formed. This aims at preventing the first insulating layer 33 and the second insulating layer 34 from being charged. To reduce the influence of the electric field, the first insulating layer 33 and the second insulating layer 34 are preferably formed into such a minimum thickness that causes no conduction (discharge). Note that the first insulating layer 33 may be joined with the first shield electrode 30 in a region among the plurality of apertures 30a of the first shield electrode 30, and the second insulating layer 34 may be joined with the second shield electrode 31 in a region among the plurality of apertures 31a of the second shield electrode 31.

As shown in FIG. 4C, the first insulating layer 33 may be arranged only in the peripheral region 30c of the first shield electrode 30, and the second insulating layer 34 may be arranged only in the peripheral region 31c of the second shield electrode 31. In this case, since the first insulating layer 33 and the second insulating layer 34 are spaced apart from the charged particle beam passing region, construction is easy in a case where, for example, the pith of the apertures 6a of the second aperture array 6 becomes narrow due to an increase in the number of charged particle beams. It is also possible to prevent the first insulating layer 33 and the second insulating layer 34 from being charged, as described above.

The effect of the present invention can be confirmed by, for example, following simulations. Charged particle beams accelerated by a voltage of 5 kV are caused to enter a silicon (Si) substrate having a thickness of 0.2 mm. The silicon substrate is cooled under predetermined conditions. In this case, thermal deformation of 3.816 μm at maximum occurs in the silicon substrate due to incidence of the charged particle beams.

Consider a case where the electric potential of the silicon substrate is lowered by 0.5 kV, and charged particle beams accelerated by a voltage of 5.5 kV are caused to enter the silicon substrate. In this case, thermal deformation of 3.840 μm at maximum occurs in the silicon substrate due to incidence of the charged particle beams. Consider a case where the electric potential of the silicon substrate is raised by 0.5 kV, and charged particle beams accelerated by a voltage of 4.5 kV are caused to enter the silicon substrate. In this case, thermal deformation of 3.793 μm at maximum occurs in the silicon substrate due to incidence of the charged particle beams. As described above, the thermal deformation amount of the silicon substrate can be changed about ±0.6% by adjusting (generating) an electric potential ±10% the acceleration voltage of 5 kV under predetermined conditions.

As described above, the drawing apparatus 100 or 100A is advantageous in reducing deformation or changes in aperture positions of an aperture array that generates a plurality of charged particle beams, and therefore suitable for manufacturing an article, for example, a micro device such as a semiconductor device or an element having a fine structure. The method of manufacturing an article includes a step of forming a latent image pattern on a photoresist applied to a substrate using the drawing apparatus 100 or 100A (a step of performing drawing on a substrate), and a step of developing the substrate on which the latent image pattern is formed in the above step (a step of developing the substrate on which the drawing has been performed). The manufacturing method can also include other known processes (for example, oxidation, deposition, vapor deposition, doping, planarization, etching, resist removal, dicing, bonding, and packaging). The method of manufacturing an article according to this embodiment is advantageous in at least one of the performance, quality, productivity, and production cost of the article, as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-110392 filed on May 24, 2013, which is hereby incorporated by reference herein in its entirety.

What is claimed:

1. A drawing apparatus for performing drawing on a substrate with a plurality of charged particle beams, the apparatus comprising:
an aperture array member in which a plurality of first apertures, for generating the plurality of charged particle beams, is formed; and
a generating device configured to individually generate electric potentials in a plurality of regions of the aperture array member,
wherein each of the plurality of regions corresponds to at least one of the plurality of first apertures.

2. The apparatus according to claim 1, further comprising:
a first shield electrode arranged on a side opposite to the substrate with respect to the aperture array member, in which a plurality of second apertures, respectively corresponding to the plurality of first apertures, is formed; and
a second shield electrode arranged on the side of the substrate with respect to the aperture array member in which a plurality of third apertures, respectively corresponding to the plurality of first apertures, is formed.

3. The apparatus according to claim 2, wherein a dimension of each of the plurality of second apertures and the plurality of third apertures is larger than a dimension of a corresponding one of the plurality of first apertures.

4. The apparatus according to claim 2, wherein
the first shield electrode is combined with the aperture array member via a first insulating layer, and
the second shield electrode is combined with the aperture array member via a second insulating layer.

5. The apparatus according to claim 4, wherein
the first insulating is in contact with a peripheral region of the first shield electrode surrounding a region where the plurality of second apertures are formed, and
the second insulating layer is in contact with the peripheral region of the second shield electrode surrounding a region where the plurality of third apertures are formed.

6. The apparatus according to claim 4, wherein
the first insulating layer is in contact with the first shield electrode in a region among the plurality of second apertures, and
the second insulating layer is in contact with the second shield electrode in a region among the plurality of third apertures.

7. The apparatus according to claim 1, further comprising a controller configured to control the electric potentials to be individually generated by the generating device, based on the plurality of first apertures respectively corresponding to the electric potentials.

8. The apparatus according to claim 1, further comprising a measurement device configured to measure positions of charged particle beams respectively transmitted via the plurality of first apertures; and
a controller configured to control the electric potentials to be individually generated by the generating device, based on the measured positions respectively corresponding to the electric potentials.

9. A method of manufacturing an article, the method comprising steps of:
performing drawing on a substrate using a drawing apparatus;
developing the substrate on which the drawing has been performed; and
processing the developed substrate to manufacture the article,
wherein the drawing apparatus performs drawing on the substrate with a plurality of charged particle beams, and includes:
an aperture array member in which a plurality of first apertures, for generating the plurality of charged particle beams, is formed; and
a generating device configured to individually generate electric potentials in a plurality of regions of the aperture array member,
wherein each of the plurality of regions corresponds to at least one of the plurality of first apertures.
